(19) United States
(12) Patent Application Publication
(10) Pub. No.: US 2025/0210558 A1
(43) Pub. Date: Jun. 26, 2025

(54) SEMICONDUCTOR DEVICE AND METHOD OF MANUFACTURING THE SAME

(71) Applicant: Kioxia Corporation, Tokyo (JP)

(72) Inventor: Nobuhiko HORI, Yokkaichi (JP)

(73) Assignee: Kioxia Corporation, Tokyo (JP)

(21) Appl. No.: 18/825,245

(22) Filed: Sep. 5, 2024

(30) Foreign Application Priority Data
Dec. 20, 2023 (JP) 2023-214996

(51) Int. Cl. H01L 23/00; H10B 41/20; H10B 41/40; H10B 43/20; H10B 43/40

(52) U.S. Cl. CPC H01L 24/08; H10B 41/20; H10B 41/40; H10B 43/20; H10B 43/40; H01L 2224/0801; H01L 2224/08146

(57) ABSTRACT

In one embodiment, a semiconductor device includes a lower insulator, and a plurality of lower pads provided in the lower insulator. The device further includes an upper insulator provided on the lower insulator, and a plurality of upper pads provided on the plurality of lower pads in the upper insulator. Furthermore, a second pad that is included in the plurality of upper pads is disposed on a first pad that is included in the plurality of lower pads, and a structure of the second pad is different from a structure of the first pad.

### CROSS REFERENCE TO RELATED APPLICATIONS

This application is based upon and claims the benefit of priority from the prior Japanese Patent Application No. 2023-214996, filed on Dec. 20, 2023, the entire contents of which are incorporated herein by reference.

### FIELD

Embodiments described herein relate to a semiconductor device and a method of manufacturing the same.

### BACKGROUND

When substrates are bonded to manufacture a semiconductor device, the substrates may not be preferably bonded due to warpage or magnification of at least one of the substrates.

### BRIEF DESCRIPTION OF THE DRAWINGS

FIG. 1 is a cross-sectional view illustrating the structure of a semiconductor device of a first embodiment;

FIG. 2 is a cross-sectional view illustrating the structure of a columnar portion CL of the first embodiment;

FIGS. 3 and 4 are cross-sectional views illustrating a method of manufacturing the semiconductor device of the first embodiment;

FIGS. 5A and 5B are perspective views schematically illustrating the shapes of an array wafer W1 and a circuit wafer W2 of the first embodiment;

FIG. 6 is a cross-sectional view illustrating a state in which the array wafer W1 and the circuit wafer W2 of a comparative example of the first embodiment are bonded;

FIG. 7 is a cross-sectional view illustrating a state in which the array wafer W1 and the circuit wafer W2 of the first embodiment are bonded;

FIG. 8 is a schematic diagram illustrating a method of manufacturing a semiconductor device of the comparative example of the first embodiment;

FIG. 9 is a schematic diagram illustrating the method of manufacturing the semiconductor device of the first embodiment;

FIGS. 10A to 10E are cross-sectional views for describing warpages of the array wafer W1 and the circuit wafer W2 of the first embodiment;

FIG. 11 is a table for describing a method of correcting metal pads 38 of the first embodiment;

FIGS. 12A and 12B are schematic plan views for describing the method of correcting the metal pads 38 of the first embodiment;

FIGS. 13A to 13D are cross-sectional views illustrating a method of manufacturing the array wafer W1 of the first embodiment;

FIGS. 14A to 14D are cross-sectional views illustrating a method of manufacturing the circuit wafer W2 of the first embodiment;

FIGS. 15A to 15F are plan views for describing the method of correcting the metal pads 38 of the first embodiment; and

FIGS. 16A to 16E are other plan views for describing the method of correcting the metal pads 38 of the first embodiment.

### DETAILED DESCRIPTION

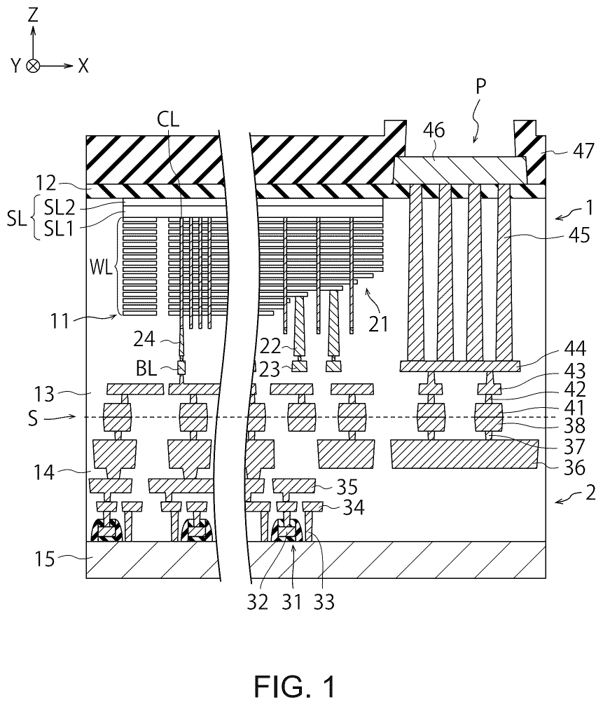

Embodiments will now be explained with reference to the accompanying drawings. In FIGS. 1 to 16, identical components are denoted by the same reference sign and duplicate description thereof is omitted.

In one embodiment, a semiconductor device includes a lower insulator, and a plurality of lower pads provided in the lower insulator. The device further includes an upper insulator provided on the lower insulator, and a plurality of upper pads provided on the plurality of lower pads in the upper insulator. Furthermore, a second pad that is included in the plurality of upper pads is disposed on a first pad that is included in the plurality of lower pads, and a structure of the second pad is different from a structure of the first pad.

### First Embodiment

FIG. 1 is a cross-sectional view illustrating the structure of a semiconductor device of a first embodiment. The semiconductor device in FIG. 1 is, for example, a three-dimensional memory. As described later, the semiconductor device in FIG. 1 is manufactured by bonding an array wafer including an array region (array chip) 1 and a circuit wafer including a circuit region (circuit chip) 2.

The array region 1 includes a memory cell array 11 including a plurality of memory cells, an insulator 12 provided on the memory cell array 11, and an inter layer dielectric 13 provided below the memory cell array 11. The memory cell array 11 is provided in the inter layer dielectric 13 below the insulator 12. The insulator 12 is, for example, a silicon oxide film (SiO2 film) or a silicon nitride film (SiN film). The inter layer dielectric 13 is, for example, a silicon oxide film or a multilayer film including a silicon oxide film and any other insulator. The inter layer dielectric 13 is an example of the upper insulator.

The circuit region 2 is provided below the array region 1. Reference sign S indicates a boundary surface (bonding surface) of the array region 1 and the circuit region 2. The circuit region 2 includes an inter layer dielectric 14 disposed below the inter layer dielectric 13, and a substrate 15 disposed below the inter layer dielectric 14. The inter layer dielectric 14 is, for example, a silicon oxide film or a multilayer film including a silicon oxide film and any other insulator. The substrate 15 is, for example, a semiconductor substrate such as a silicon (Si) substrate. The inter layer dielectric 14 is an example of the lower insulator. The substrate 15 is an example of a lower substrate.

FIG. 1 illustrates an X direction and a Y direction parallel to the surface of the substrate 15 and orthogonal to each other, and a Z direction orthogonal to the surface of the substrate 15. The X, Y, and Z directions intersect each other. In the present specification, the positive Z direction is treated as the upward direction, and the negative Z direction is treated as the downward direction. The negative Z direction may be or may not be aligned with the direction of gravity.

The array region 1 includes, as a plurality of electrode layers in the memory cell array 11, a plurality of word lines WL and a source line SL. FIG. 1 illustrates a staircase structure portion 21 of the memory cell array 11. Each word line WL is electrically connected to a word interconnect layer 23 through a contact plug 22. Each columnar portion CL penetrating through the above-described plurality of word lines WL is electrically connected to a bit line BL through a via plug 24 and also electrically connected to the source line SL. The source line SL includes a lower layer SL1 that is a semiconductor layer, and an upper layer SL2 that is a metal layer.

The circuit region 2 includes a plurality of transistors 31 in the inter layer dielectric 14. Each transistor 31 includes a gate electrode 32 provided on the substrate 15 with a gate insulator interposed therebetween, and a source diffusing layer and a drain diffusing layer provided in the substrate 15, which are not illustrated. The circuit region 2 also includes a plurality of contact plugs 33 provided on the gate electrodes 32, the source diffusing layers, or the drain diffusing layers of the transistors 31, an interconnect layer 34 provided on the contact plugs 33 and including a plurality of interconnects, and an interconnect layer 35 provided on the interconnect layer 34 and including a plurality of interconnects.

The circuit region 2 also includes an interconnect layer 36 provided on the interconnect layer 35 and including a plurality of interconnects, a plurality of via plugs 37 provided on the interconnect layer 36, and a plurality of metal pads 38 provided on the via plugs 37. The metal pads 38 are disposed near the bonding surface S in the inter layer dielectric 14. The metal pads 38 are each, for example, a metal layer including a copper (Cu) layer. The circuit region 2 functions as a control circuit (logic circuit) configured to control operation of the array region 1. The control circuit is constituted by the transistors 31 and the like and electrically connected to the metal pads 38. The metal pads 38 are each an example of a lower pad.

The array region 1 includes a plurality of metal pads 41 provided on the above-described plurality of metal pads 38, and a plurality of via plugs 42 provided on the metal pads 41. The array region 1 also includes an interconnect layer 43 provided on the via plugs 42 and including a plurality of interconnects, and an interconnect layer 44 provided on the interconnect layer 43 and including a plurality of interconnects. The metal pads 41 are disposed near the bonding surface S in the inter layer dielectric 13. The metal pads 41 are each, for example, a metal layer including a Cu layer. The above-described bit line BL is included in the interconnect layer 44. The above-described control circuit is electrically connected to the memory cell array 11 through the metal pads 41 and 38 and the like and controls operation of the memory cell array 11 through the metal pads 41 and 38 and the like. The metal pads 41 are each an example of an upper pad.

The array region 1 also includes a plurality of via plugs 45 provided on the interconnect layer 44, a metal pad 46 provided on the via plugs 45 and the insulator 12, and a passivation film 47 provided on the metal pad 46 and the insulator 12. The metal pad 46 is, for example, a metal layer including a Cu layer and functions as an external connecting pad (bonding pad) of the semiconductor device in FIG. 1. The passivation film 47 is, for example, a stacked insulator including a silicon oxide film and a silicon nitride film and has an opening portion P through which the upper surface of the metal pad 46 is exposed. The metal pad 46 is connectable to a mounting substrate or another device by a bonding wire, a soldering ball, a metal bump, or the like through the opening portion P.

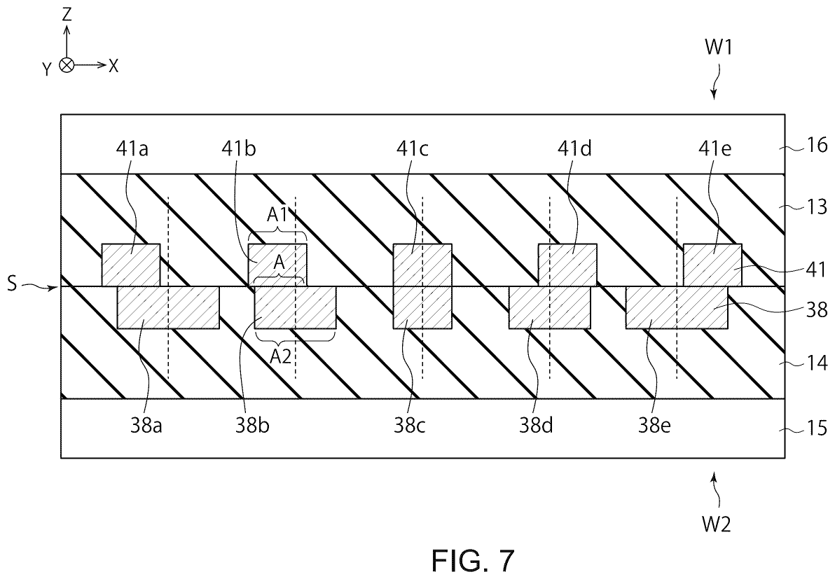

More specifically, the metal pads 38 and 41 of the present embodiment have structures illustrated in FIG. 7 or the like to be described later. Further details of the metal pads 38 and 41 of the present embodiment will be described later.

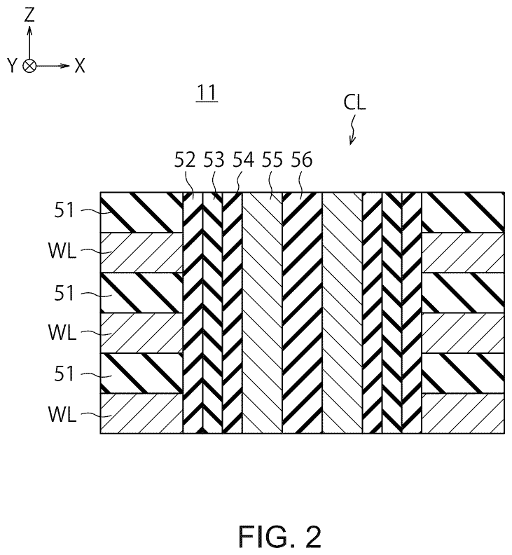

FIG. 2 is a cross-sectional view illustrating the structure of each columnar portion CL of the first embodiment. FIG. 2 illustrates one of the plurality of columnar portions CL illustrated in FIG. 1.

As illustrated in FIG. 2, the memory cell array 11 includes the plurality of word lines WL and a plurality of insulators 51 alternately stacked on the inter layer dielectric 13 (refer to FIG. 1). The word lines WL are each, for example, a metal layer including a tungsten (W) layer. The insulators 51 are each, for example, a silicon oxide film.

The columnar portion CL sequentially includes a block insulator 52, an electric charge accumulating layer 53, a tunnel insulator 54, a channel semiconductor layer 55, and a core insulator 56. The electric charge accumulating layer 53 is, for example, an insulator such as a silicon nitride film and formed on side surfaces of the word lines WL and the insulators 51 with the block insulator 52 interposed therebetween. The electric charge accumulating layer 53 may be a semiconductor layer such as a polysilicon layer. The channel semiconductor layer 55 is, for example, a polysilicon layer and formed on a side surface of the electric charge accumulating layer 53 with the tunnel insulator 54 interposed therebetween. The block insulator 52, the tunnel insulator 54, and the core insulator 56 are each, for example, a silicon oxide film or a metal insulator.

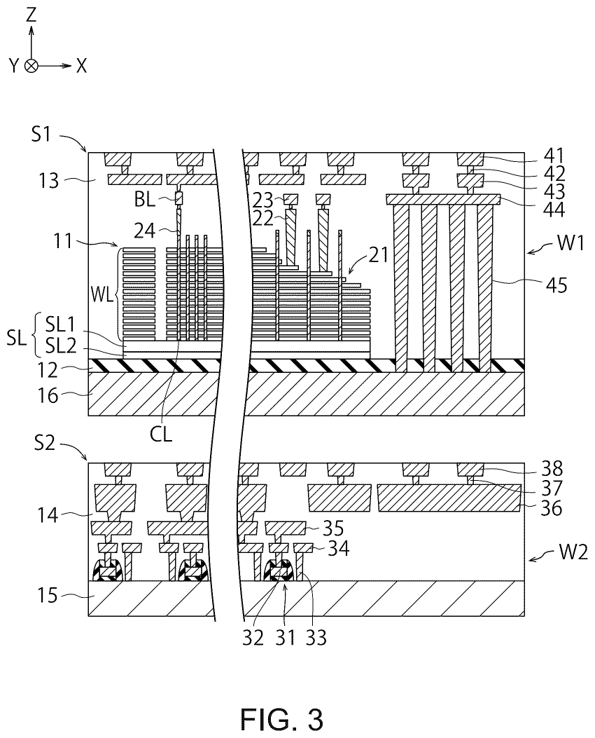

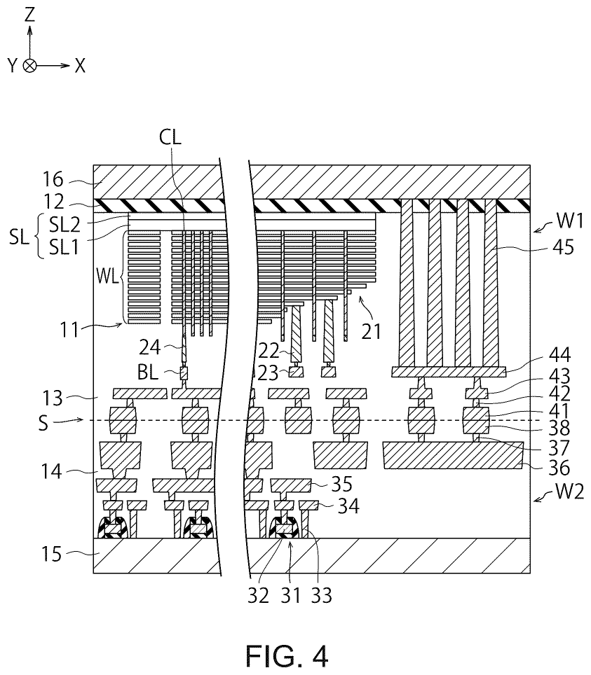

FIGS. 3 and 4 are cross-sectional views illustrating a method of manufacturing the semiconductor device of the first embodiment. FIG. 3 illustrates an array wafer W1 including a plurality of array regions 1, and a circuit wafer W2 including a plurality of circuit regions 2. The orientation of the array wafer W1 in FIG. 3 is opposite the orientation of the array region 1 in FIG. 1. In the present embodiment, the array wafer W1 and the circuit wafer W2 are bonded to manufacture the semiconductor device. FIG. 3 illustrates the array wafer W1 the orientation of which is yet to be inverted for bonding, and FIG. 1 illustrates the array region 1 the orientation of which is inverted for bonding and that is bonded and diced. The array wafer W1 is an example of an upper wafer. The circuit wafer W2 is an example of a lower wafer.

In FIG. 3, reference sign S1 indicates the upper surface of the array wafer W1, and reference sign S2 indicates the upper surface of the circuit wafer W2. The array wafer W1 includes a substrate 16 disposed below the insulator 12. The substrate 16 is, for example, a semiconductor substrate such as a silicon substrate. The substrate 16 is an example of an upper substrate.

In the present embodiment, first, as illustrated in FIG. 3, the memory cell array 11, the insulator 12, the inter layer dielectric 13, the staircase structure portion 21, the metal pads 41, and the like are formed on the substrate 16 of the array wafer W1, and the inter layer dielectric 14, the transistors 31, the metal pads 38, and the like are formed on the substrate 15 of the circuit wafer W2. For example, the via plugs 45, the interconnect layer 44, the interconnect layer 43, the via plugs 42, and the metal pads 41 are sequentially formed on the substrate 16. In addition, the contact plugs 33, the interconnect layer 34, the interconnect layer 35, the interconnect layer 36, the via plugs 37, and the metal pads 38 are sequentially formed on the substrate 15. Subsequently, as illustrated in FIG. 4, the array wafer W1 and the circuit wafer W2 are bonded by mechanical pressure so that the surface S1 faces the surface S2. Accordingly, the inter layer dielectric 13 and the inter layer dielectric 14 are adhered together. Specifically, the inter layer dielectric 13 is disposed on the inter layer dielectric 14, and each metal pad 41 is disposed on the corresponding metal pad 38. Subsequently, the array wafer W1 and the circuit wafer W2 are annealed. Accordingly, the metal pads 41 and the metal pads 38 are joined together. In this manner, the substrate 16 and the substrate 15 are bonded through the inter layer dielectrics 13 and 14.

Thereafter, the thickness of the substrate 15 is reduced by chemical mechanical polishing (CMP) and the substrate 16 is removed by CMP, and then the array wafer W1 and the circuit wafer W2 are disconnected into a plurality of chips. In this manner, the semiconductor device in FIG. 1 is manufactured. The metal pad 46 and the passivation film 47 are formed on the insulator 12, for example, after thickness reduction of the substrate 15 and removal of the substrate 16.

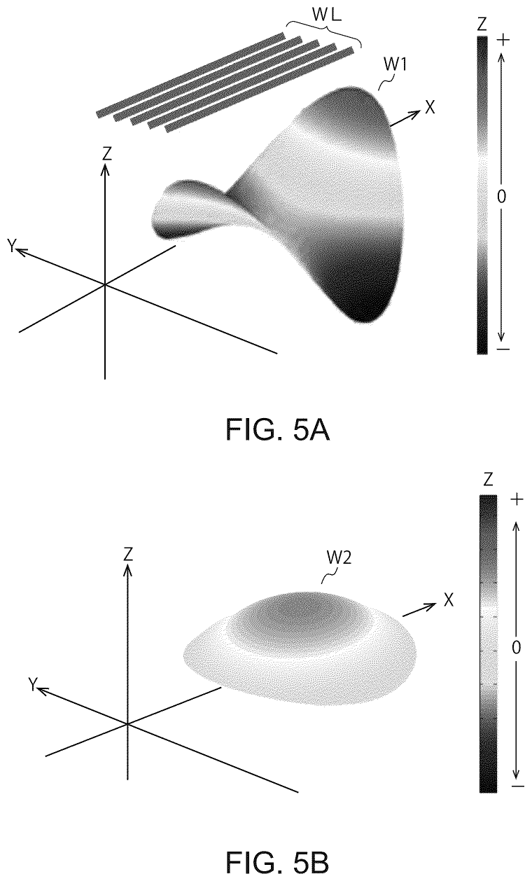

Although the array wafer W1 and the circuit wafer W2 are bonded in the present embodiment, the array wafers W1 may be bonded instead. Contents described above with reference to FIGS. 1 to 4 and contents to be described later with reference to FIGS. 5 to 16 are also applicable to bonding of the array wafers W1.

Although FIG. 1 illustrates a boundary surface of the inter layer dielectric 13 and the inter layer dielectric 14 and a boundary surface of the metal pads 41 and the metal pads 38, it is typical that these boundary surfaces are not observed after the above-described annealing. However, the positions where these boundary surfaces were can be estimated by detecting, for example, tilts of side surfaces of the metal pads 41 and side surfaces of the metal pads 38 or positional misalignment between the side surfaces of the metal pads 41 and the side surfaces of the metal pads 38.

The semiconductor device of the present embodiment may be subjected to transaction in the state in FIG. 1 after disconnection into a plurality of chips or may be subjected to transaction in the state in FIG. 4 before disconnection into a plurality of chips. FIG. 1 illustrates the semiconductor device in a chip state, and FIG. 4 illustrates the semiconductor device in a wafer state. In the present embodiment, the semiconductor device (FIG. 1) in the state of being a plurality of chips is manufactured from the semiconductor device (FIG. 4) in the state of being one wafer.

FIGS. 5A and 5B are perspective views schematically illustrating the shapes of the array wafer W1 and the circuit wafer W2 of the first embodiment.

In the present embodiment, when the memory cell array 11, the insulator 12, the inter layer dielectric 13, and the like are formed on the substrate 16 (refer to FIG. 3), warpage occurs to the substrate 16 due to influence of the memory cell array 11, the insulator 12, the inter layer dielectric 13, and the like. As a result, the array wafer W1 warps as illustrated in FIG. 5A. However, in FIG. 5A, the warpage having occurred to the array wafer W1 is illustrated larger than actual warpage for the clarity of the drawing.

In FIG. 5A, the warpage of the array wafer W1 (substrate 16) occurs such that the direction of the warpage at a section in the X direction is opposite the direction of the warpage at a section in the Y direction. For example, the array wafer W1 warps in a shape convex downward at an XZ section passing through the center of the array wafer W1. In addition, the array wafer W1 warps in a shape convex upward at a YZ section passing through the center of the array wafer W1. Accordingly, the warpage of the array wafer W1 in FIG. 5A occurs such that the direction of the warpage at the XZ section is opposite the direction of the warpage at the YZ section.

Such warpage of the array wafer W1 occurs due to, for example, influence of the word lines WL. FIG. 5A schematically illustrates the word lines WL extending in the X direction. The shape of the word lines WL has large anisotropy between the X and Y directions, which leads to such warpage of the array wafer W1.

Similarly, when the inter layer dielectric 14 and the like are formed on the substrate 15 (refer to FIG. 3), warpage occurs to the substrate 15 due to influence of the inter layer dielectric 14 and the like. As a result, the circuit wafer W2 warps as illustrated in FIG. 5B. However, in FIG. 5B, the warpage having occurred to the circuit wafer W2 is illustrated larger than actual warpage for the clarity of the drawing.

In FIG. 5B, the warpage of the circuit wafer W2 (substrate 15) occurs such that the direction of the warpage at a section in the X direction is the same as the direction of the warpage at a section in the Y direction. For example, the circuit wafer W2 warps in a shape convex upward at an XZ section passing through the center of the circuit wafer W2. In addition, the circuit wafer W2 warps in a shape convex upward at a YZ section passing through the center of the circuit wafer W2. Accordingly, the warpage of the circuit wafer W2 in FIG. 5B occurs such that the direction of the warpage at the XZ section is the same as the direction of the warpage at the YZ section.

The circuit wafer W2 includes no constituent components having large shape anisotropy between the X and Y directions like the word lines WL. Accordingly, the warpage of the array wafer W1 anisotropically occurs, but the warpage of the circuit wafer W2 isotropically occurs. In other words, the warpage state of the circuit wafer W2 is different from the warpage state of the array wafer W1. Typically, the array wafer W1 more largely warps than the circuit wafer W2, and thus the warpage of the array wafer W1 often causes problems.

Furthermore, when the memory cell array 11, the insulator 12, the inter layer dielectric 13, and the like are formed on the substrate 16, not only warpage occurs to the substrate 16 but also change occurs to magnification of the substrate 16 due to influence of the memory cell array 11, the insulator 12, the inter layer dielectric 13, and the like. Change of the magnification of the substrate 16 is expansion or shrinkage of the substrate 16 in plan view due to stress of the inter layer dielectric 13 or the like. Similarly, when the inter layer dielectric 14 and the like are formed on the substrate 15, not only warpage occurs to the substrate 15 but also change occurs to magnification of the substrate 15 due to influence of the inter layer dielectric 14 and the like. Typically, the magnitude and direction of stress of the inter layer dielectric 14 are different from the magnitude and direction of stress of the inter layer dielectric 13, and accordingly, the magnification state of the circuit wafer W2 is different from the magnification state of the array wafer W1.

The warpage state of a wafer can be detected by measuring, for example, the warpage amount of the wafer or the warpage differential value of the wafer. The magnification state of the wafer can be detected by measuring, for example, the magnification value of the wafer or the magnification difference of the wafer. Details of these measurements will be described later.

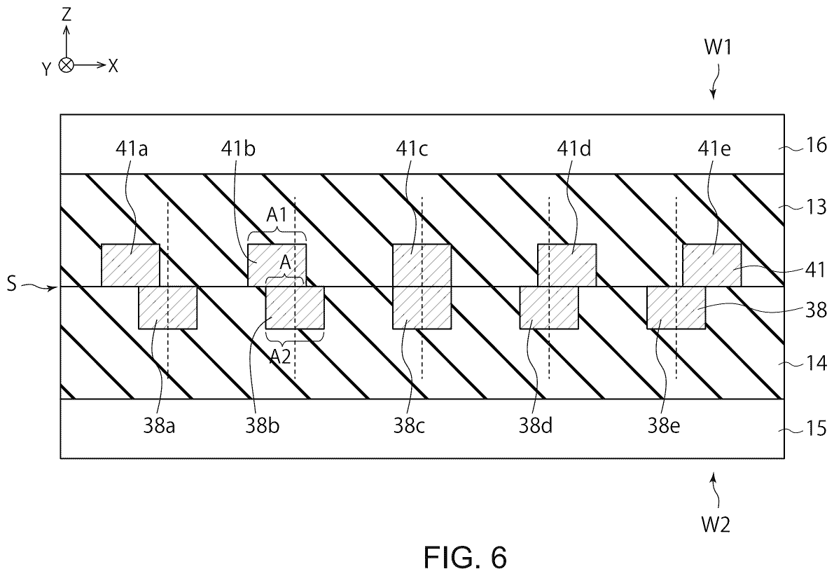

In the following, the semiconductor device of the present embodiment is compared with a semiconductor device of a comparative example of the present embodiment with reference to FIGS. 6 to 9.

FIG. 6 is a cross-sectional view illustrating a state in which the array wafer W1 and the circuit wafer W2 of the comparative example of the first embodiment are bonded.

FIG. 6 corresponds to an enlarged view of FIG. 4. FIG. 6 illustrates the substrate 16, the inter layer dielectric 13, and the plurality of metal pads 41 of the array wafer W1 and the substrate 15, the inter layer dielectric 14, and the plurality of metal pads 38 of the circuit wafer W2, and omits illustrations of the other constituent components illustrated in FIG. 4.

FIG. 6 also illustrates metal pads 38a to 38e included in the above-described plurality of metal pads 38, and metal pads 41a to 41e included in the above-described plurality of metal pads 41. The metal pads 41a to 41e correspond to the metal pads 38a to 38e, respectively. Accordingly, the metal pads 41a to 41e are disposed on the metal pads 38a to 38e and electrically connected to the metal pads 38a to 38e, respectively. In FIG. 6, the metal pad 41c is positioned on the central axis of the array wafer W1, and the metal pad 38c is positioned on the central axis of the circuit wafer W2. The metal pads 38a to 38e are each an example of a first pad. The metal pads 41a to 41e are each an example of a second pad.

In the present comparative example, the structure of the metal pad 41a is the same as the structure of the metal pad 38a. Specifically, the shape of the metal pad 41a in plan view is congruent with the shape of the metal pad 38a in plan view, the orientation of the metal pad 41a in plan view is the same as the orientation of the metal pad 38a in plan view, and the thickness of the metal pad 41a is equal to the thickness of the metal pad 38a.

In the present comparative example, the shape of the metal pad 38a in plan view is the shape (square) of the upper surface of the metal pad 38a, and the shape of the metal pad 41a in plan view is the shape (square) of the lower surface of the metal pad 41a. Accordingly, the shape of the metal pad 38a in plan view and the shape of the metal pad 41a in plan view are congruent squares. Moreover, the shape of the upper surface of the metal pad 38a is a square having four sides parallel to the X or Y direction, and the shape of the lower surface of the metal pad 41a is a square having four sides parallel to the X or Y direction. Accordingly, the orientation of the metal pad 41a in plan view is the same as the orientation of the metal pad 38a in plan view. The above-described relation also holds between the metal pads 38b and 41b, between the metal pads 38c and 41c, between the metal pads 38d and 41d, and between the metal pads 38e and 41e.

Thus, the metal pads 38a and 41a of the present comparative example should be disposed such that the metal pads 41a and 38a completely overlap in plan view if there is no positional misalignment between the metal pads 38a and 41a.

However, in the present comparative example, positional misalignment occurs between the metal pads 38a and 41a because the warpage and magnification states of the circuit wafer W2 are different from the warpage and magnification states of the array wafer W1. As a result, the metal pads 38a and 41a of the present comparative example are disposed such that the metal pads 41a and 38a partially overlap in plan view. Accordingly, electric properties of the metal pads 38a and 41a potentially degrade, such as increase in electric resistance between the metal pads 38a and 41a. This is the same for the metal pads 38b and 41b, the metal pads 38d and 41d, and the metal pads 38e and 41e. However, such a problem does not occur to the metal pads 38c and 41c since the metal pads 38c and 41c are disposed on the above-described central axis. Typically, positional misalignment between the metal pads 38 and 41 increases as the distance between the central axis of the array wafer W1 and the metal pads 41 increases.

FIG. 6 illustrates area A1 of each metal pad 41 in plan view, area A2 of each metal pad 38 in plan view, and joint area A of metal pads 41 and 38 corresponding to each other. The joint area A is the area of a joint portion between the upper surface of the metal pad 38 and the lower surface of the metal pad 41.

In the present comparative example, the shape of the metal pad 41a in plan view is congruent with the shape of the metal pad 38a in plan view. Accordingly, the area A1 of the metal pad 41a is equal to the area A2 of the metal pad 38a (A1=A2). Moreover, in the present comparative example, the orientation of the metal pad 41a in plan view is the same as the orientation of the metal pad 38a in plan view. Thus, if there is no positional misalignment between the metal pads 38a and 41a, the metal pads 41a and 38a should be disposed completely overlapping each other in plan view, and the joint area A of the metal pads 41a and 38a should be equal to the area A1 of the metal pad 41a and equal to the area A2 of the metal pad 38a (A=A1 and A=A2). However, in the present comparative example, since positional misalignment occurs between the metal pads 38a and 41a, the joint area A of the metal pads 41a and 38a is smaller than the area A1 of the metal pad 41a and smaller than the area A2 of the metal pad 38a (A<A1 and A<A2). This is the same for the metal pads 38b and 41b, the metal pads 38d and 41d, and the metal pads 38e and 41e.

Dashed lines illustrated in FIG. 6 indicate the central axes of the metal pads 38a to 38e. Accordingly, the distance between these dashed lines represents the pitch between the metal pads 38a to 38e. Similarly, the pitch between the metal pads 41a to 41e is represented by the distance between the central axes of the metal pads 41a to 41e. In the present comparative example, the pitch between the metal pads 41a to 41e is different from the pitch between the metal pads 38a to 38e due to influence of the warpages and magnifications of the array wafer W1 and the circuit wafer W2.

FIG. 7 is a cross-sectional view illustrating a state in which the array wafer W1 and the circuit wafer W2 of the first embodiment are bonded.

FIG. 7 is an enlarged view similar to FIG. 6. As in FIG. 6, FIG. 7 illustrates the metal pads 38a to 38e included in the plurality of metal pads 38 and the metal pads 41a to 41e included in the plurality of metal pads 41. The following describes difference between the present embodiment and the above-described comparative example about the metal pads 38a to 38e and the metal pads 41a to 41e.

In the present embodiment, the structure of the metal pad 41a is different from the structure of the metal pad 38a. Specifically, the shape of the metal pad 41a in plan view is non-congruent with the shape of the metal pad 38a in plan view. The thickness of the metal pad 41a is equal to the thickness of the metal pad 38a in the present embodiment but may be different from the thickness of the metal pad 38a. As described later, in a case where the shape of the metal pad 41a in plan view is congruent with the shape of the metal pad 38a in plan view, the orientation of the metal pad 41a in plan view may be different from the orientation of the metal pad 38a in plan view. In this manner, the metal pads 38a and 41a having structures different from each other can be achieved in various forms.

In the present embodiment, the shape of the metal pad 38a in plan view is the shape (rectangle) of the upper surface of the metal pad 38a, and the shape of the metal pad 41a in plan view is the shape (square) of the lower surface of the metal pad 41a. Accordingly, the shape of the metal pad 38a in plan view is non-congruent with the shape of the metal pad 41a in plan view. Moreover, the shape of the upper surface of the metal pad 38a is a rectangle having two long sides parallel to the X direction and two short sides parallel to the Y direction, and the shape of the lower surface of the metal pad 41a is a square having four sides parallel to the X or Y direction. Accordingly, the metal pad 41a in plan view and the metal pad 38a in plan view each have sides parallel to the X direction and sides parallel to the Y direction. The above-described relation also holds between the metal pads 38b and 41b, between the metal pads 38d and 41d, and between the metal pads 38e and 41e. The relation between the metal pads 38c and 41c is the same as the relation in the above-described comparative example.

In the present embodiment, the structure of the metal pad 38a is corrected when the metal pad 38a is formed in the inter layer dielectric 14. Specifically, the shape of the metal pad 38a in plan view is changed from a square as in FIG. 6 to a rectangle as in FIG. 7 when the metal pad 38a is formed in the inter layer dielectric 14. As a result, the metal pad 38a in the shape illustrated in FIG. 7 is formed. In a case where such correction is not performed, the metal pad 38a in the shape illustrated in FIG. 6 is formed. According to the present embodiment, with such correction, the joint area A of the metal pads 41a and 38a after the correction can be made larger than the joint area A of the metal pads 41a and 38a before the correction (refer to FIGS. 6 and 7).

As described above, positional misalignment occurs between the metal pads 38a and 41a in a case where the warpage and magnification states of the circuit wafer W2 are different from the warpage and magnification states of the array wafer W1. Thus, in the present embodiment, a value indicating the state of the array wafer W1 is measured before the metal pad 38a is formed in the inter layer dielectric 14. Examples of such a value are a value related to the warpage state of the array wafer W1 and a value related to the magnification of the array wafer W1. In the present embodiment, the structure of the metal pad 38a is corrected based on a measurement result of the value indicating the state of the array wafer W1. For example, an increase amount (correction amount) of the area A2 of the metal pad 38a is increased as the magnitude of a warpage amount of the array wafer W1 is larger. This makes it possible to increase the joint area A of the metal pads 41a and 38a and suppress degradation of electric properties of the metal pads 38a and 41a. This is the same for the metal pads 38b and 41b, the metal pads 38d and 41d, and the metal pads 38e and 41e. However, correction of the structure of the metal pad 38a is unnecessary because positional misalignment between the metal pads 38c and 41c causes no problem in the present embodiment.

In the present embodiment, the shape of the metal pad 41a in plan view is non-congruent with the shape of the metal pad 38a in plan view. Accordingly, the area A1 of the metal pad 41a is different from the area A2 of the metal pad 38a (A1≠A2). Specifically, since the area A2 of the metal pad 38a is increased by correction, the area A1 of the metal pad 41a is smaller than the area A2 of the metal pad 38a (A1<A2). In the present embodiment, to ensure the large joint area A of the metal pads 41a and 38a, the joint area A of the metal pads 41a and 38a is desirably set to be equal to or larger than 40% of the area A1 of the metal pad 41a and/or equal to or larger than 40% of the area A2 of the metal pad 38a (A≥0.4×A1 and/or A≥0.4×A2). As for the metal pads 41a and 38a in FIG. 7, the joint area A is equal to or larger than 40% of the area A1 and smaller than 40% of the area A2. This is the same for the metal pads 38b and 41b, the metal pads 38d and 41d, and the metal pads 38e and 41e. As for the metal pads 38c and 41c, A=A1=A2 holds.

Dashed lines illustrated in FIG. 7 indicate the central axes of the metal pads 38a to 38e. Accordingly, the distance between these dashed lines represents the pitch between the metal pads 38a to 38e. Similarly, the pitch between the metal pads 41a to 41e is represented by the distance between the central axes of the metal pads 41a to 41e. In the present embodiment, as in the above-described comparative example, the pitch between the metal pads 41a to 41e is different from the pitch between the metal pads 38a to 38e due to influence of the warpages and magnifications of the array wafer W1 and the circuit wafer W2. Moreover, the pitch between the metal pads 38a to 38e illustrated in FIG. 7 is different from the pitch between the metal pads 38a to 38e illustrated in FIG. 6. This indicates change of the pitch between the metal pads 38a to 38e by correction.

Instead of being performed based on the value indicating the state of the array wafer W1, the above-described correction may be performed based on a value indicating the state of the circuit wafer W2 or may be performed based on the value indicating the state of the array wafer W1 and the value indicating the state of the circuit wafer W2. In the present embodiment, it is assumed that the warpage and the like of the circuit wafer W2 are smaller than the warpage and the like of the array wafer W1, and the above-described correction is performed based on only the value indicating the state of the array wafer W1. Similarly, instead of being performed on the metal pads 38, the above-described correction may be performed on the metal pads 41 or may be performed on the metal pads 38 and 41.

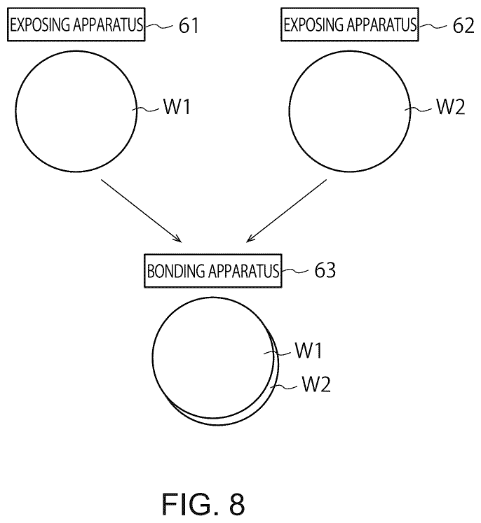

FIG. 8 is a schematic diagram illustrating a method of manufacturing the semiconductor device of the comparative example of the first embodiment.

In the present comparative example, when the metal pads 41 are to be formed in the inter layer dielectric 13 of the array wafer W1, a resist layer is formed on the inter layer dielectric 13 and patterned by using an exposing apparatus 61. Subsequently, a plurality of pad trenches are formed in the inter layer dielectric 13 by etching using the resist layer, and the metal pads 41 are formed in the pad trenches. Thus, the shapes and orientations of the metal pads 41 in plan view are determined mainly by patterning of the resist layer, and the thicknesses of the metal pads 41 are determined mainly by etching of the pad trenches.

Similarly, when the metal pads 38 are to be formed in the inter layer dielectric 14 of the circuit wafer W2, a resist layer is formed on the inter layer dielectric 14 and patterned by using an exposing apparatus 62. Subsequently, a plurality of pad trenches are formed in the inter layer dielectric 14 by etching using the resist layer, and the metal pads 38 are formed in the pad trenches. Thus, the shapes and orientations of the metal pads 38 in plan view are determined mainly by patterning of the resist layer, and the thicknesses of the metal pads 38 are determined mainly by etching of the pad trenches. The exposing apparatus 62 may be the same as the exposing apparatus 61 or may be different from the exposing apparatus 61.

Thereafter, the array wafer W1 and the circuit wafer W2 are bonded by using a bonding apparatus 63. In this manner, the structure illustrated in FIG. 6 is achieved.

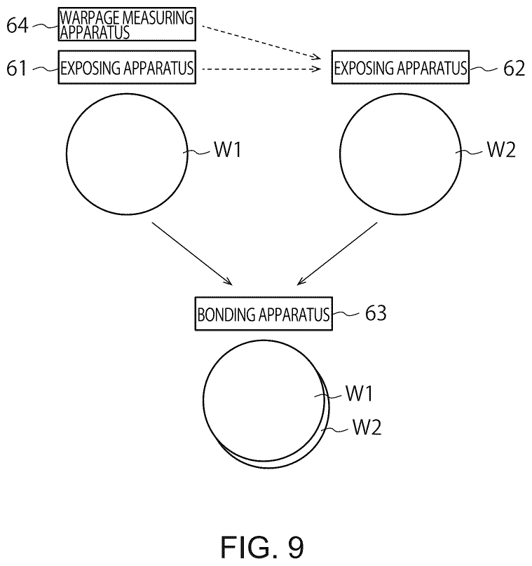

FIG. 9 is a schematic diagram illustrating the method of manufacturing the semiconductor device of the first embodiment.

In the present embodiment as well, when the metal pads 41 are to be formed in the inter layer dielectric 13 of the array wafer W1, a resist layer is formed on the inter layer dielectric 13 and patterned by using the exposing apparatus 61. Subsequently, a plurality of pad trenches are formed in the inter layer dielectric 13 by etching using the resist layer, and the metal pads 41 are formed in the pad trenches. Moreover, in the present embodiment, a value related to the warpage of the array wafer W1 is measured by a warpage measuring apparatus 64, and a value related to the magnification of the array wafer W1 is measured by the exposing apparatus 61. The value measured by the warpage measuring apparatus 64 and the value measured by the exposing apparatus 61 are provided from the warpage measuring apparatus 64 and the exposing apparatus 61 to the exposing apparatus 62.

Similarly, when the metal pads 38 are to be formed in the inter layer dielectric 14 of the circuit wafer W2, a resist layer is formed on the inter layer dielectric 14 and patterned by using the exposing apparatus 62. In this case, the exposing apparatus 62 corrects the shape and orientation of a resist pattern for the metal pads 38 based on the values provided from the warpage measuring apparatus 64 and the exposing apparatus 61 (feedforward correction). Subsequently, a plurality of pad trenches are formed in the inter layer dielectric 14 by etching using the resist layer, and the metal pads 38 are formed in the pad trenches. As a result, the shapes and orientations of the metal pads 38 are corrected due to influence of the correction of the resist pattern. In a case where the thicknesses of the metal pads 38 are to be corrected, the depths of the pad trenches are corrected based on the values provided from the warpage measuring apparatus 64 and the exposing apparatus 61 (feedforward correction).

Thereafter, the array wafer W1 and the circuit wafer W2 are bonded by using the bonding apparatus 63. In this manner, the structure illustrated in FIG. 7 is achieved.

Through correction of the shapes of the metal pads 38, the shapes of the metal pads 38 in plan view are changed, for example, from the shapes illustrated in FIG. 6 to the shapes illustrated in FIG. 7. In this case, in the correction performed by the exposing apparatus 62, exposure data used to expose a resist layer is changed from exposure data for forming the metal pads 38 in FIG. 6 to exposure data for forming the metal pads 38 in FIG. 7. Accordingly, the shape of the resist pattern for the metal pads 38 is corrected, and as a result, the shapes of the metal pads 38 are corrected.

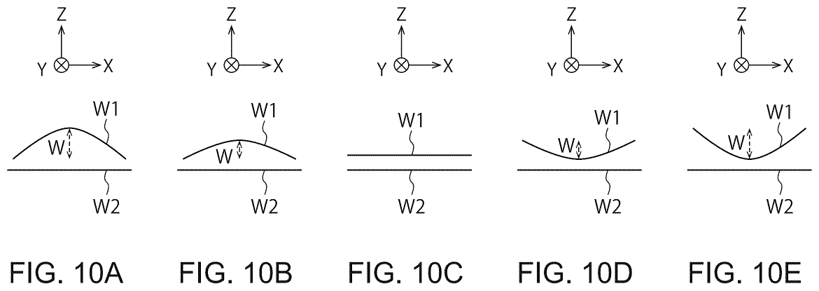

FIGS. 10A to 10E are cross-sectional views for describing the warpages of the array wafer W1 and the circuit wafer W2 of the first embodiment.

FIGS. 10A to 10E illustrate five states of the array wafer W1 and the circuit wafer W2. The array wafer W1 in FIG. 10A significantly warps in a shape convex upward, and the array wafer W1 in FIG. 10B slightly warps in a shape convex upward. The array wafer W1 in FIG. 10C does not warp. The array wafer W1 in FIG. 10D slightly warps in a shape convex downward, and the array wafer W1 in FIG. 10E significantly warps in a shape convex downward. The circuit wafer W2 does not warp in any of FIGS. 10A to 10E.

FIGS. 10A, 10B, 10D, and 10E each illustrate a warpage amount W of the array wafer W1. In this example, the magnitude of the warpage amount W is a maximum protrusion amount of the array wafer W1 relative to the edge of the array wafer W1. The value of the warpage amount W is defined to be negative in FIGS. 10A and 10B, zero in FIG. 10C, and positive in FIGS. 10D and 10E. Accordingly, among FIGS. 10A to 10E, the warpage amount W in FIG. 10A is smallest and the warpage amount W in FIG. 10E is largest. The magnitude (absolute value) of the warpage amount W is large in FIGS. 10A and 10E and small in FIGS. 10B and 10D.

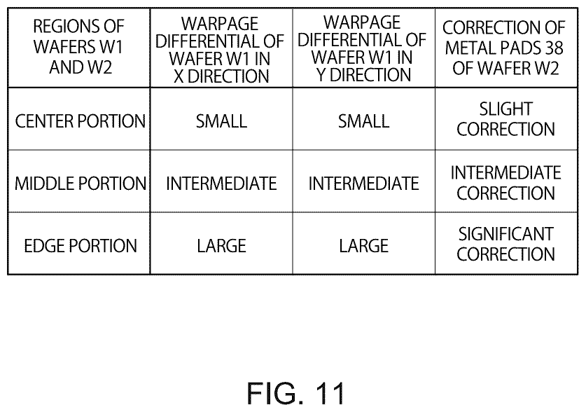

FIG. 11 is a table for describing a method of correcting the metal pads 38 of the first embodiment.

FIG. 11 illustrates an example in which the structures of the metal pads 38 of the circuit wafer W2 are corrected based on the value of the warpage differential of the array wafer W1. A center portion, an edge portion, and a middle portion of each wafer correspond to a portion near the central axis of the wafer, a portion near the edge of the wafer, and a portion between the center and edge portions of the wafer, respectively. The warpage differential of the array wafer W1 in the X direction indicates the surface slope of the array wafer W1 at an XZ section of the array wafer W1. The warpage differential of the array wafer W1 in the Y direction indicates the surface slope of the array wafer W1 at a YZ section of the array wafer W1.

In FIG. 11, the warpage differentials of the center portion of the array wafer W1 in the X and Y directions are small, and thus the structures of the metal pads 38 at the center portion of the circuit wafer W2 are slightly corrected. However, the warpage differentials of the edge portion of the array wafer W1 in the X and Y directions are large, and thus the structures of the metal pads 38 at the edge portion of the circuit wafer W2 are significantly corrected. The status of such correction is exemplarily illustrated in FIG. 7.

The exposing apparatus 62 (FIG. 9) of the present embodiment holds, as a library in advance, the relation between the values measured by the exposing apparatus 61 and the warpage measuring apparatus 64 and exposure conditions of the exposing apparatus 62. Then, when having received the values measured by the exposing apparatus 61 and the warpage measuring apparatus 64, the exposing apparatus 62 of the present embodiment determines exposure conditions based on the received values and the library. This makes it possible to perform correction as illustrated in FIG. 7.

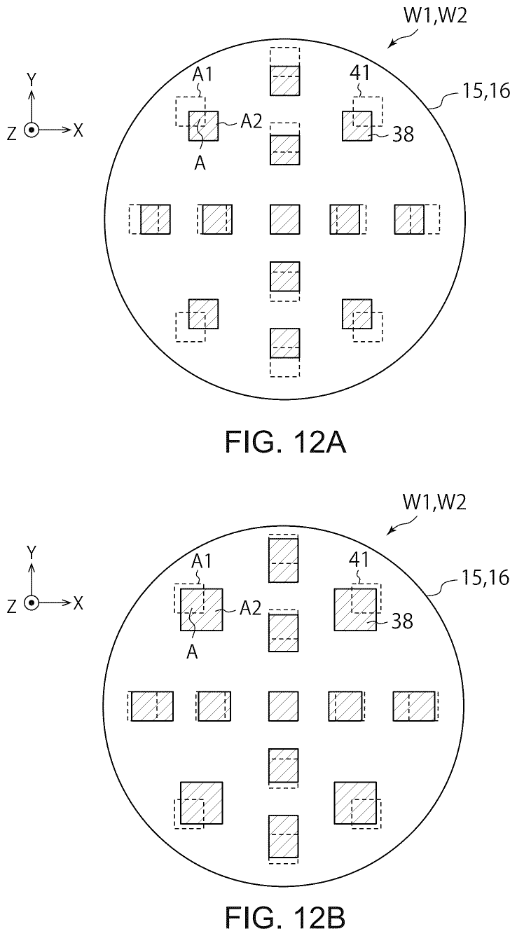

FIGS. 12A and 12B are schematic plan views for describing the method of correcting the metal pads 38 of the first embodiment.

As in FIG. 6, FIG. 12A illustrates a state in which the array wafer W1 and the circuit wafer W2 are bonded according to the above-described comparative example. In the present comparative example, the shape of each metal pad 41 in plan view is a square, and the shape of each metal pad 38 in plan view is a square. Moreover, in each pair of metal pads 38 and 41, the shape of the metal pad 41 in plan view is congruent with the shape of the metal pad 38 in plan view, and the orientation of the metal pad 41 in plan view is the same as the orientation of the metal pad 38 in plan view.

As in FIG. 7, FIG. 12B illustrates a state in which the array wafer W1 and the circuit wafer W2 are bonded according to the present embodiment. In the present embodiment, the shape of each metal pad 41 in plan view is a square, and the shape of each metal pad 38 in plan view is a square or a rectangle. Moreover, in each pair of metal pads 38 and 41, the shape of the metal pad 41 in plan view is non-congruent with the shape of the metal pad 38 in plan view (except for a pair of metal pads 38 and 41 at the center). In each pair of metal pads 38 and 41 illustrated in FIG. 12B, the joint area A is equal to or larger than 40% of the area A1.

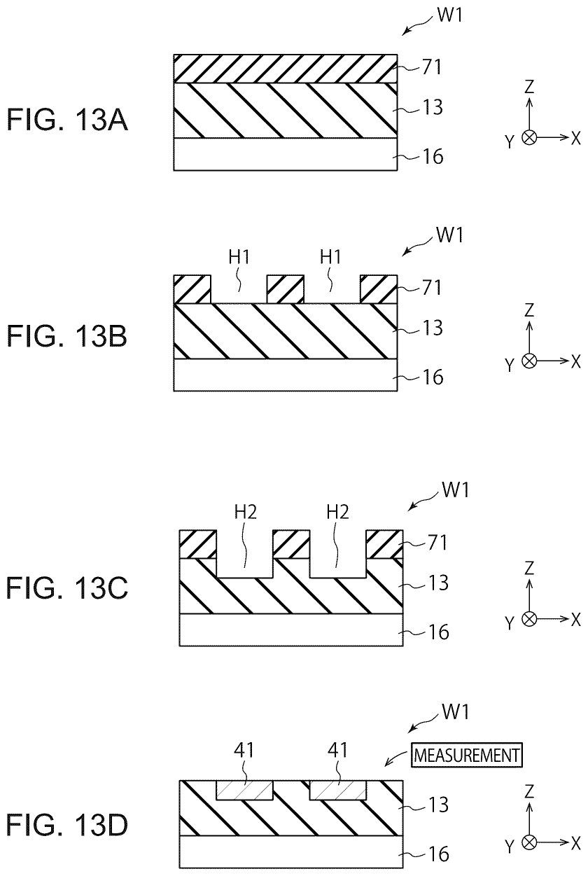

FIGS. 13A to 13D are cross-sectional views illustrating a method of manufacturing the array wafer W1 of the first embodiment.

FIG. 13A illustrates the substrate 16, the inter layer dielectric 13 formed on the substrate 16, and a resist layer 71 formed on the inter layer dielectric 13. When the metal pads 41 are to be formed in the inter layer dielectric 13 of the array wafer W1, the resist layer 71 is formed on the inter layer dielectric 13 (FIG. 13A). The resist layer 71 may be formed on the inter layer dielectric 13 with a hard mask layer in between. Subsequently, the resist layer 71 is patterned by using the exposing apparatus 61 (FIG. 9) (FIG. 13B). FIG. 13B illustrates a plurality of opening portions H1 formed through the resist layer 71.

Subsequently, a plurality of pad trenches H2 are formed in the inter layer dielectric 13 by etching using the resist layer 71 (FIG. 13C). Subsequently, the resist layer 71 is removed, and then the metal pads 41 are formed in the pad trenches H2 (FIG. 13D). Moreover, in the present embodiment, the value related to the warpage of the array wafer W1 is measured by the warpage measuring apparatus 64 (FIG. 9), and the value related to the magnification of the array wafer W1 is measured by the exposing apparatus 61. The timing of the measurement may be a timing other than the timing of the process in FIG. 13D. The value measured by the warpage measuring apparatus 64 and the value measured by the exposing apparatus 61 are provided from the warpage measuring apparatus 64 and the exposing apparatus 61 to the exposing apparatus 62.

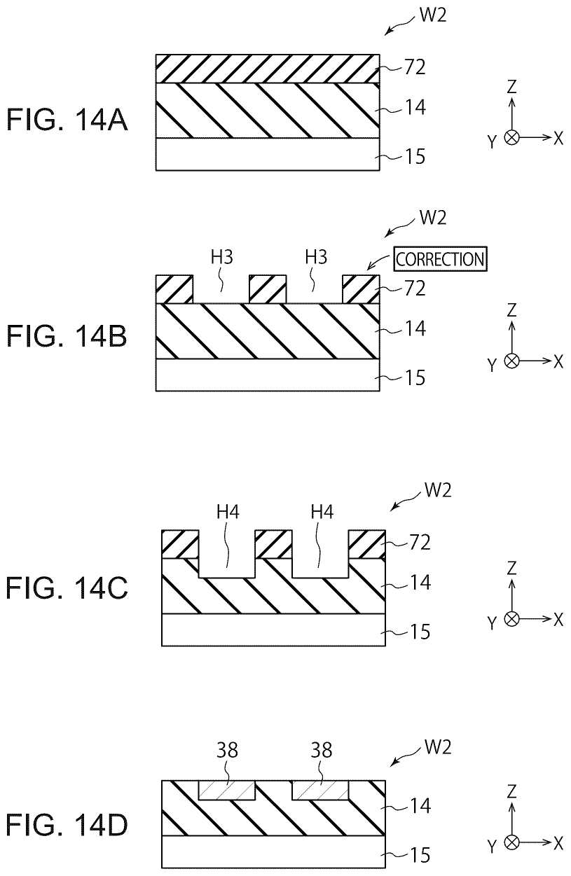

FIGS. 14A to 14D are cross-sectional views illustrating a method of manufacturing the circuit wafer W2 of the first embodiment.

FIG. 14A illustrates the substrate 15, the inter layer dielectric 14 formed on the substrate 15, and a resist layer 72 formed on the inter layer dielectric 14. When the metal pads 38 are to be formed in the inter layer dielectric 14 of the circuit wafer W2, the resist layer 72 is formed on the inter layer dielectric 14 (FIG. 14A). The resist layer 72 may be formed on the inter layer dielectric 14 with a hard mask layer in between. Subsequently, the resist layer 72 is patterned by using the exposing apparatus 62 (FIG. 9) (FIG. 14B). FIG. 14B illustrates a plurality of opening portions H3 formed through the resist layer 72. Through the process in FIG. 14B, the exposing apparatus 62 corrects the shapes and orientations of the opening portions H3 based on the values provided from the warpage measuring apparatus 64 and the exposing apparatus 61.

Subsequently, a plurality of pad trenches H4 are formed in the inter layer dielectric 14 by etching using the resist layer 72 (FIG. 14C). Subsequently, the resist layer 72 is removed, and then the metal pads 38 are formed in the pad trenches H4 (FIG. 14D). As a result, the shapes and orientations of the metal pads 38 are corrected due to influence of correction of the opening portions H3.

Thereafter, the array wafer W1 and the circuit wafer W2 are bonded by using the bonding apparatus 63 (FIG. 9). In this manner, the structure illustrated in FIG. 7 is achieved.

FIGS. 13A to 14B omit illustrations of the via plugs 42 and the interconnect layer 43 below the metal pads 41 and illustrations of the via plugs 37 and the interconnect layer 36 below the metal pads 38. When the shapes and orientations of the metal pads 38 are corrected, some metal pads 38 are potentially short-circuited with any of the via plugs 37 and any of the interconnect layer 36. In this case, the thicknesses of the metal pads 38 may be corrected to avoid the short circuit.

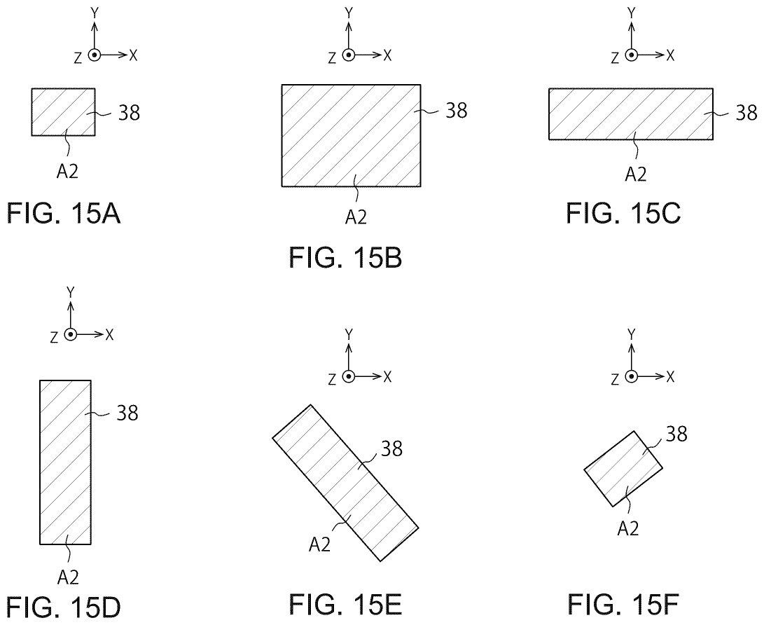

FIGS. 15A to 15F are plan views for describing the method of correcting the metal pads 38 of the first embodiment.

FIG. 15A illustrates an example of a metal pad 38 before the correction. The planar shape of the metal pad 38 in FIG. 15A is a rectangle. FIGS. 15B to 15F illustrate examples of the metal pad 38 after the correction.

FIG. 15B illustrates an example in which the planar shape of the metal pad 38 in FIG. 15A is enlarged in the X and Y directions. FIG. 15C illustrates an example in which the planar shape of the metal pad 38 in FIG. 15A is enlarged in the X direction. FIG. 15D illustrates an example in which the orientation of the metal pad 38 in FIG. 15C is rotated by 90°. FIG. 15E illustrates an example in which the orientation of the metal pad 38 in FIG. 15C is rotated by 45°. FIG. 15F illustrates an example in which the orientation of the metal pad 38 in FIG. 15A is rotated by 45°.

In FIGS. 15B to 15E, the shape of the metal pad 38 in plan view is corrected from FIG. 15A. In FIG. 15F, the orientation of the metal pad 38 in plan view is corrected from FIG. 15A.

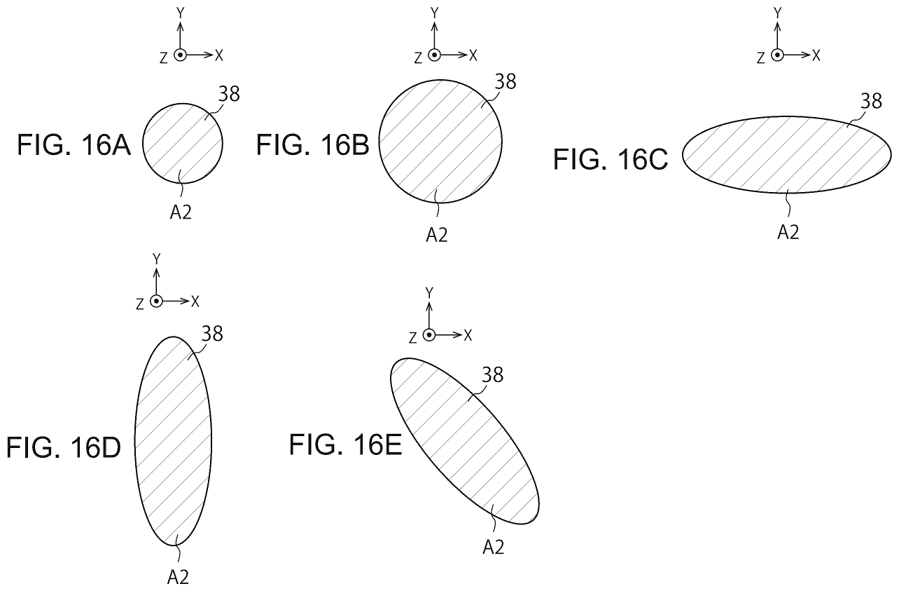

FIGS. 16A to 16E are other plan views for describing the method of correcting the metal pads 38 of the first embodiment.

FIG. 16A illustrates an example of a metal pad 38 before the correction. The planar shape of the metal pad 38 in FIG. 16A is a circle.

FIGS. 16B to 16E illustrate examples of the metal pad 38 after the correction.

FIG. 16B illustrates an example in which the planar shape of the metal pad 38 in FIG. 16A is enlarged in the X and Y directions. FIG. 16C illustrates an example in which the planar shape of the metal pad 38 in FIG. 16A is enlarged in the X direction. FIG. 16D illustrates an example in which the orientation of the metal pad 38 in FIG. 16C is rotated by 90°. FIG. 16E illustrates an example in which the orientation of the metal pad 38 in FIG. 16C is rotated by 45°.

In FIGS. 16B to 16E, the shape of the metal pad 38 in plan view is corrected from FIG. 16A.

As described above, the semiconductor device of the present embodiment includes combinations of the metal pads 38 and 41 in which the structure of a metal pad 38 is different from the structure of the corresponding metal pad 41. Thus, according to the present embodiment, the array wafer W1 and the circuit wafer W2 can be preferably bonded in any of a case where warpage occurs to the array wafer W1 and/or the circuit wafer W2 and a case where change occurs to the magnification of the array wafer W1 and/or the circuit wafer W2.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a lower insulator;
a plurality of lower pads provided in the lower insulator;
an upper insulator provided on the lower insulator; and
a plurality of upper pads provided on the plurality of lower pads in the upper insulator,
wherein
a second pad that is included in the plurality of upper pads is disposed on a first pad that is included in the plurality of lower pads, and
a structure of the second pad is different from a structure of the first pad.

2. The device of claim 1, wherein a shape of the second pad in plan view is non-congruent with a shape of the first pad in plan view.

3. The device of claim 1, wherein an area of the second pad in plan view is different from an area of the first pad in plan view.

4. The device of claim 1, wherein a shape of the second pad in plan view is congruent with a shape of the first pad in plan view, and an orientation of the second pad in plan view is different from an orientation of the first pad in plan view.

5. The device of claim 1, wherein a thickness of the second pad is different from a thickness of the first pad.

6. The device of claim 1, wherein a joint area of the first pad and the second pad is equal to or larger than 40% of an area of the first pad in plan view and/or is equal to or larger than 40% of an area of the second pad in plan view.

7. The device of claim 1, wherein a pitch between the upper pads is different from a pitch between the lower pads.

8. The device of claim 1, further comprising:
a memory cell array provided in the upper insulator; and
a control circuit provided in the lower insulator and configured to control the memory cell array.

9. A semiconductor device comprising:
a lower wafer that includes a lower insulator, and a plurality of lower pads provided in the lower insulator; and
an upper wafer that includes an upper insulator provided on the lower insulator, and a plurality of upper pads provided on the plurality of lower pads in the upper insulator,
wherein
a second pad that is included in the plurality of upper pads is disposed on a first pad that is included in the plurality of lower pads, and
a structure of the second pad is different from a structure of the first pad.

10. The device of claim 9, wherein
the lower wafer further includes a lower substrate provided below the lower insulator, and
the upper wafer further includes an upper substrate provided on the upper insulator.

11. The device of claim 10, wherein a state of a warpage of the upper substrate is different from a state of a warpage of the lower substrate.

12. The device of claim 10, wherein a state of a magnification of the upper substrate is different from a state of a magnification of the lower substrate.

13. A method of manufacturing a semiconductor device, comprising:
forming a lower insulator on a lower substrate of a lower wafer;
forming a plurality of lower pads in the lower insulator;
forming an upper insulator on an upper substrate of an upper wafer;
forming a plurality of upper pads in the upper insulator; and
bonding the lower wafer and the upper wafer to dispose the upper insulator on the lower insulator and dispose the plurality of upper pads on the plurality of lower pads,
wherein
a second pad that is included in the plurality of upper pads is disposed on a first pad that is included in the plurality of lower pads, and
a structure of the second pad is different from a structure of the first pad.

14. The method of claim 13, wherein the first pad and the second pad are formed such that a joint area of the first pad and the second pad is equal to or larger than 40% of an area of the first pad in plan view and/or is equal to or larger than 40% of an area of the second pad in plan view.

15. The method of claim 13, further comprising measuring a value representing a state of the lower substrate or the upper substrate,
wherein the first pad and the second pad are formed based on the value such that the structure of the second pad is different from the structure of the first pad.

16. The method of claim 15, wherein the value is related to a warpage of the lower substrate or the upper substrate.

17. The method of claim 15, wherein the value is related to a magnification of the lower substrate or the upper substrate.

18. The method of claim 15, further comprising correcting structures of the lower pads or the upper pads based on the value, when the lower pads or the upper pads are formed,
wherein the first pad and the second pad are formed such that the structure of the second pad before the correction is same as the structure of the first pad before the correction, and the structure of the second pad after the correction is different from the structure of the first pad after the correction.

19. The method of claim 18, wherein the correction is performed such that a joint area of the first pad and a second pad after the correction is larger than a joint area of the first pad and the second pad before the correction.

20. The method of claim 18, wherein the correction is performed such that a pitch between the lower pads or the upper pads after the correction is different from a pitch between the lower pads or the upper pads before the correction.
